(19) United States
(12) Patent Application Publication
(10) Pub. No.: US 2014/0224333 A1
(43) Pub. Date: Aug. 14, 2014

(54) PHOTOELECTRIC CONVERSION DEVICE

(71) Applicants: Shintaro Kubo, Kirishima-shi (JP); Hideaki Asao, Kyotanabe-shi (JP); Seiichiro Inai, Omihachiman-shi (JP); Hisakazu Ninomiya, Kirishima-shi (JP); Shuji Nakazawa, Suwon (KR)

(72) Inventors: Shintaro Kubo, Kirishima-shi (JP); Hideaki Asao, Kyotanabe-shi (JP); Seiichiro Inai, Omihachiman-shi (JP); Hisakazu Ninomiya, Kirishima-shi (JP); Shuji Nakazawa, Suwon (KR)

(73) Assignee: KYOCERA CORPORATION, Kyoto-shi, Kyoto (JP)

(21) Appl. No.: 14/235,774

(22) PCT Filed: Jul. 27, 2012
(86) PCT No.: PCT/JP2012/069128

§ 371 Date: Jan. 28, 2014

(30) Foreign Application Priority Data
Jul. 29, 2011 (JP) 2011-166717

(51) Int. Cl. H01L 31/032

(52) U.S. Cl. CPC H01L 31/0322
USPC 136/265

(57) ABSTRACT

A photoelectric converter is disclosed. The photoelectric converter includes a light-absorbing layer. The light-absorbing layer includes a plurality of crystalline grains. The grains contain a Group I-III-VI chalcopyrite compound semiconductor. The light-absorbing layer contains oxygen and an average atomic concentration of oxygen at grain boundaries of the light-absorbing layer is larger than the average atomic concentration of oxygen in the grains of the light-absorbing layer.

### TECHNICAL FIELD

The present invention relates to a photoelectric converter.

### BACKGROUND ART

Japanese Unexamined Patent Application Publication No. 8-330614 discloses a photovoltaic cell including a light-absorbing layer containing a Group I-III-VI compound semiconductor such as CIS (copper indium diselenide) or CIGS (copper indium gallium diselenide). Photoelectric converters such as photovoltaic cells containing a Group I-III-VI compound semiconductor need to have increased photoelectric conversion efficiency.

It is an object of the present invention to increase the photoelectric conversion efficiency of a photoelectric converter.

### DISCLOSURE OF INVENTION

A photoelectric converter according to an embodiment of the present invention includes a light-absorbing layer which is polycrystalline, and in which a plurality of grains are bonded, wherein each of the grains contains a Group I-III-VI chalcopyrite compound semiconductor. In this embodiment, the light-absorbing layer contains oxygen. In this embodiment, an average atomic concentration of oxygen at grain boundaries of the light-absorbing layer is larger than the average atomic concentration of oxygen in the grains of the light-absorbing layer.

In a photoelectric converter according to an embodiment of the present invention, the photoelectric conversion efficiency can be enhanced.

### BRIEF DESCRIPTION OF DRAWINGS

FIG. 1 is a perspective view showing an example of a photoelectric converter according to an embodiment of the present invention.

FIG. 2 is a sectional view showing an example of a photoelectric converter according to an embodiment of the present invention.

### DESCRIPTION OF EMBODIMENTS

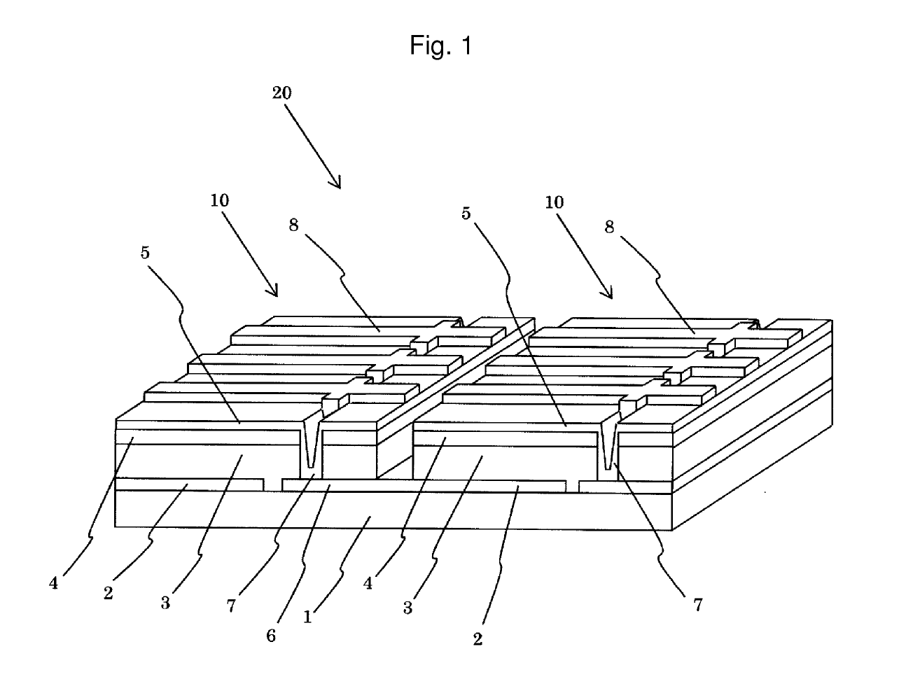

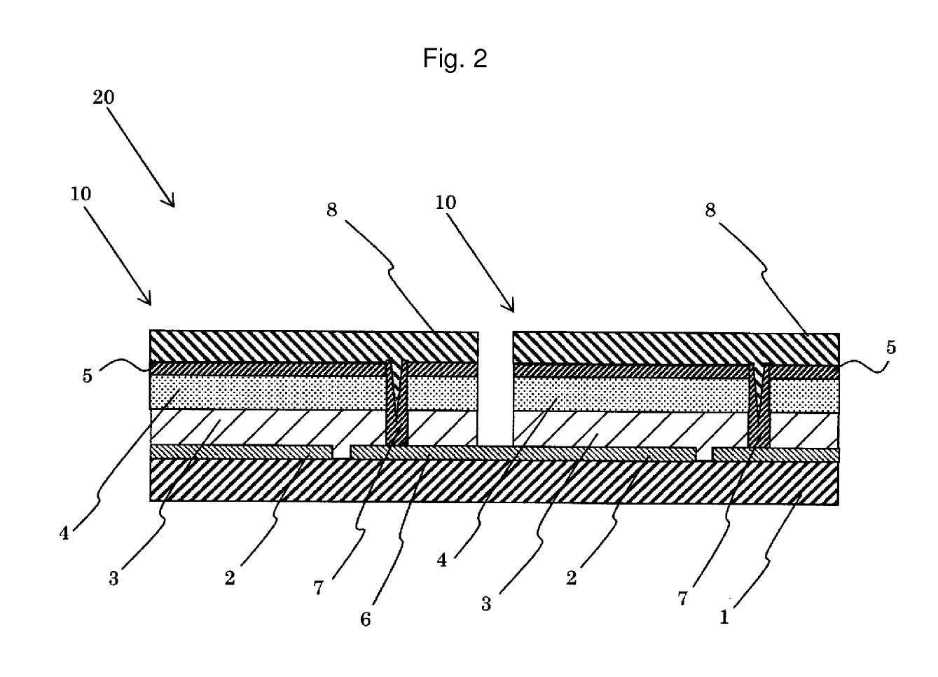

A photoelectric converter 10 according to an embodiment of the present invention includes a substrate 1, a first electrode layer 2, light-absorbing layers 3, buffer layers 4, and second electrode layers 5 as shown in FIGS. 1 and 2. The photoelectric converter 10 includes a third electrode layer 6 which is located on the substrate 1 side of the light-absorbing layers 3 and which is spaced from the first electrode layer 2. The photoelectric converter 10 and an adjacent photoelectric converter 10 are electrically connected to each other through a connection conductor 7. That is, the second electrode layers 5 of one of the photoelectric converters 10 are electrically connected to the third electrode layer 6 of the other photoelectric converter 10 through the connection conductor 7. This third electrode layer 6 functions as the first electrode layer 2 of the adjacent photoelectric converter 10. This allows the neighboring photoelectric converters 10 to be connected to each other in series. In one of the photoelectric converters 10, the connection conductor 7 is placed so as to separate the light-absorbing layers 3 and the buffer layers 4. Therefore, in each photoelectric converter 10, photoelectric conversion is carried out by the light-absorbing layers 3 and the buffer layers 4, which are interposed between the first electrode layer 2 and the second electrode layers 5. That is, in the photoelectric converter 10, the light-absorbing layers 3 and the buffer layers 4 function as photoelectric conversion layers. In this embodiment, current-collecting electrodes 8 may be placed on each second electrode layer 5.

The substrate 1 supports the photoelectric converter 10. A material used in the substrate 1 is, for example, glass, ceramic, resin, or the like.

The first electrode layer 2 and the third electrode layer 6 are made of, for example, molybdenum (Mo), aluminum (Al), titanium (Ti), gold (Au), or the like. The first electrode layer 2 and the third electrode layer 6 are formed on the substrate 1 by, for example, a sputtering process, a vapor deposition process, or the like.

The light-absorbing layers 3 absorb light and carry out photoelectric conversion in cooperation with the buffer layers 4. The light-absorbing layers 3 contain a chalcopyrite compound semiconductor and are placed on the first electrode layer 2 and the third electrode layer 6. Herein, the chalcopyrite compound semiconductor is a compound semiconductor (also referred to as “CIS compound semiconductor”) containing a Group I-B element (also referred to as “group 11 element”), a Group III-B element (also referred to as “group 13 element”), and a Group VI-B element (also referred to as “group 16 element”). Examples of the Group I-III-V chalcopyrite compound semiconductor include Cu(In, Ga)Se₂ (also referred to as “CIGS”), Cu(In, Ga)(Se, S)₂ (also referred to as “CIGSS”), and CuInS₂ (also referred to as “CIS”). Incidentally, the term “Cu(In, Ga)Se₂” refers to a compound mainly containing Cu, In, Ga, and Se. The term “Cu(In, Ga)(Se, S)₂” refers to a compound mainly containing Cu, In, Ga, Se, and S.

The light-absorbing layers 3 may have a thickness of, for example, 1 μm to 2.5 μm. This leads to an increase in photoelectric conversion efficiency.

The light-absorbing layers 3 are polycrystalline semiconductor layers each composed of a plurality of joined grains (crystal grains) containing the Group I-III-VI chalcopyrite compound semiconductor. The grains may have an average diameter of, for example, 0.2 μm to 1 μm. This allows the adhesion to the first electrode layer 2 and the third electrode layer 6 to be increased. The average diameter of the grains is measured as described below. Ten impartial arbitrary spots in a cross section of each light-absorbing layer 3 are photographed with a scanning electron microscope (SEM), whereby images (also referred to as “cross-sectional images”) are obtained. Next, a transparent film is put on each cross-sectional image and grain boundaries are traced with a pen through the transparent film. In this operation, a straight line (also referred to as “scale bar”) showing a certain distance (for example, 1 μm) displayed near a corner of the cross-sectional image is also traced with the pen. The transparent film on which the grain boundaries and the scale bar are written with the pen is read with a scanner, whereby image data is obtained. The area of each grain is calculated from the image data using predetermined image-processing software. Next, the diameter of the grain is calculated from the area thereof on the assumption that the grain is spherical. The diameters of the grains captured in the ten cross-sectional images are averaged, whereby the average diameter is calculated.

Furthermore, the light-absorbing layers 3 contain oxygen. Such oxygen has a function of repairing defects present in the chalcopyrite compound semiconductor. The defects refer to regions where atoms are eliminated from some sites of a chalcopyrite structure. Oxygen can enter the regions where atoms are eliminated to repair the defects. In other words, oxygen replaces the regions where atoms are eliminated from some sites of the chalcopyrite structure. This allows the defects to be repaired by oxygen; hence, the occurrence of the recombination of carriers is reduced.

Oxygen is bonded to the chalcopyrite compound semiconductor and therefore is present in grains of the chalcopyrite compound semiconductor. Furthermore, oxygen is present at the grain boundaries.

In this embodiment, the average atomic concentration of oxygen at grain boundaries in each light-absorbing layer 3 is greater than the average atomic concentration of oxygen in grains in the light-absorbing layer 3. This allows the energy gap between the conduction band of the grain boundaries and the valence band in the grains to be large; hence, the recombination of electrons and holes is reduced. As a result, the short-circuit current (Jsc) can be increased and therefore the photoelectric conversion efficiency is increased.

On the other hand, in the light-absorbing layer 3, when the atomic concentration of oxygen is excessively high, a large amount of oxygen is present in regions other than regions having defects in some cases. In such a case, oxygen itself may possibly cause defects. Therefore, the average atomic concentration of oxygen in the grains in the light-absorbing layer 3 is preferably 1 atomic percent to 10 atomic percent. When the atomic concentration of oxygen therein is within such a range, the occurrence of defects due to oxygen can be reduced and defects present in the chalcopyrite compound semiconductor can be repaired.

The average atomic concentration of oxygen at the grain boundaries in the light-absorbing layer 3 may be 10 atomic percent to 30 atomic percent higher than the average atomic concentration of oxygen in the grains in the light-absorbing layer 3. This allows the energy gap between the conduction band of the grain boundaries and the valence band in the grains to be large; hence, the recombination of electrons and holes is reduced.

Incidentally, the average atomic concentration of oxygen at the grain boundaries in the light-absorbing layer 3 and that of oxygen in the grains in the light-absorbing layer 3 can be measured in such a way that five spots in each of the grains and the grain boundaries are analyzed for composition by energy dispersive X-ray spectroscopy (EDS) using, for example, a transmission electron microscope (TEM). An average value obtained from the five spots is the average atomic concentration of oxygen at the grain boundaries or in the grains.

Ten spots in each of the grains and grain boundaries in the light-absorbing layer 3 have been actually analyzed for composition by energy dispersive X-ray spectroscopy using a transmission electron microscope. As a result, the average atomic concentration of oxygen at the grain boundaries in the light-absorbing layer 3 was 17 atomic percent. Furthermore, the atomic concentration of oxygen in the grains in the light-absorbing layer 3 was 0.5 atomic percent. In addition, the photoelectric conversion efficiency of the photoelectric converter 10, which included the light-absorbing layer 3, was 14.7%. In the photoelectric converter 10, the recombination of electrons and holes is reduced, leading to an increase in photoelectric conversion efficiency. Incidentally, a photoelectric converter including a light-absorbing layer in which the average atomic concentration of oxygen at grain boundaries was substantially equal to that of oxygen in grains had a photoelectric conversion efficiency of 13.4%.

The elemental ratio of oxygen to the Group III-B element at the grain boundaries in the light-absorbing layer 3 may be greater than the elemental ratio of oxygen to the Group III-B element in the grains in the light-absorbing layer 3. This allows atoms of oxygen to enter defects due to atoms of the Group VI-B element, such as selenium or sulfur; hence, the recombination of electrons and holes, which are likely to recombine with each other at grain boundaries, is likely to be reduced. In this case, the elemental ratio of oxygen to the Group III-B element in the grains in the light-absorbing layer 3 may range from 0.01 to 0.10. The elemental ratio of oxygen to the Group III-B element at the grain boundaries in the light-absorbing layer 3 may be 1.2 times to 3 times the elemental ratio of oxygen to the Group III-B element in the grains in the light-absorbing layer 3.

An example of a method for preparing the light-absorbing layer 3 is described below. First, raw materials of the light-absorbing layer 3 are described. A raw-material solution for the light-absorbing layer 3 may contain, for example, a Group I-B metal, a Group III-B metal, a chalcogen element-containing organic compound, and a Lewis-basic organic solvent. A solvent (hereinafter also referred to as “mixed solvent S”) containing the chalcogen element-containing organic compound and Lewis-basic organic solvent is likely to dissolve the Group I-B metal and the Group III-B metal. The raw-material solution can be prepared using the mixed solvent S such that the sum of the concentration of the Group I-B metal and that of the Group III-B metal with respect to the mixed solvent S is 6% by mass or more. The use of the mixed solvent S allows the solubility of the above metals to be increased; hence, the raw-material solution can be obtained so as to have high concentration. The raw-material solution is described below in detail.

The chalcogen element-containing organic compound is an organic compound containing a chalcogen element. The chalcogen element is S, Se, or Te among Group VI-B elements. When the chalcogen element is S, examples of the chalcogen element-containing organic compound include thiols, sulfides, disulfides, thiophenes, sulfoxides, sulfones, thioketones, sulfonic acids, sulfonic esters, and sulfuric diamides. Among these compounds, the thiols, the sulfides, and the disulfides are likely to form complexes with metals. When the chalcogen element-containing organic compound has a phenyl group, the chalcogen element-containing organic compound can enhance coating properties. Examples of such a compound include thiophenol, diphenyl sulfide, and derivatives thereof.

When the chalcogen element is Se, examples of the chalcogen element-containing organic compound include selenols, selenides, diselenides, selenoxides, and selenones. Among these compounds, the selenols, the selenides, and the diselenides are likely to form complexes with metals. In addition, phenylselenol, phenyl selenide, diphenyl diselenide, and derivatives thereof have a phenyl group and can enhance coating properties.

When the chalcogen element is Te, examples of the chalcogen element-containing organic compound include tellurols, tellurides, and ditellurides.

The Lewis-basic organic solvent is an organic solvent containing a substance capable of serving as a Lewis base. Examples of the Lewis-basic organic solvent include pyridine, aniline, triphenylphosphine, and derivatives thereof. When the Lewis-basic organic solvent has a boiling point of 100° C. or higher, the Lewis-basic organic solvent can enhance coating properties.

The Group I-B metal is preferably chemically bonded to the chalcogen element-containing organic compound. Furthermore, the Group III-B metal is preferably chemically bonded to the chalcogen element-containing organic compound. Moreover, the chalcogen element-containing organic compound is preferably chemically bonded to the Lewis-basic organic solvent. The raw-material solution is readily prepared so as to have a high concentration of 8% by mass or more because of such chemical bonding. Examples of the chemical bonding include coordination bonds between elements. The chemical bonding can be confirmed by, for example, an NMR (nuclear magnetic resonance) technique. In the NMR technique, the chemical bond between the Group I-B metal and the chalcogen element-containing organic compound can be detected as a shift in the multi-NMR peak of the chalcogen element. The chemical bond between the Group III-B metal and the chalcogen element-containing organic compound can be detected as a shift in the multi-NMR peak of the chalcogen element. The chemical bond between the chalcogen element-containing organic compound and the Lewis-basic organic solvent can be detected as a shift in a peak originating from the organic solvent. The number of moles of the chemical bond between the Group I-B metal and the chalcogen element-containing organic compound may be 0.1 times to 10 times the number of moles of the chemical bond between the chalcogen element-containing organic compound and the Lewis-basic organic solvent.

The mixed solvent S may be prepared by mixing the chalcogen element-containing organic compound with the Lewis-basic organic solvent so as to be liquid at room temperature. This allows the mixed solvent S to be readily handled. The chalcogen element-containing organic compound may be mixed with the Lewis-basic organic solvent such that the amount of the chalcogen element-containing organic compound is 0.1 times to 10 times the amount of the Lewis-basic organic solvent. This enables the above-mentioned chemical bonds to be formed well. As a result, a high-concentration solution containing the Group I-B metal and the Group III-B metal is readily obtained.

The raw-material solution can be obtained by, for example, directly dissolving the Group I-B metal and the Group III-B metal in the mixed solvent S. In such a way, the contamination of the light-absorbing layer 3 with impurities other than components of a compound semiconductor can be reduced. Incidentally, either of the Group I-B metal and the Group III-B metal may be a metal salt. Herein, the expression “directly dissolving the Group I-B metal and the Group III-B metal in the mixed solvent S” means that a block of a single metal or a block of alloy is directly mixed with the mixed solvent S and is dissolved therein. This means that the block of the single metal or alloy need not be dissolved in a solvent after the block of the single metal or alloy is once converted into another compound (for example, a metal salt such as a chloride). Therefore, this way enables steps to be simplified and allows the contamination of the light-absorbing layer 3 with impurities other than elements making up the light-absorbing layer 3 to be reduced. This allows the purity of the light-absorbing layer 3 to be increased.

The Group I-B metal is, for example, Cu, Ag, or the like. The Group I-B metal may be a type of element or may contain two or more types of elements. In the case of using two or more types of Group I-B metals, a mixture of two or more types of elements may be dissolved in the mixed solvent S at once. On the other hand, solutions prepared by separately dissolving Group I-B metals in the mixed solvent S may be mixed together.

The Group III-B metal is, for example, Ga, In, or the like. The Group III-B metal may be a type of element or may contain two or more types of elements. In the case of using two or more types of Group III-B metals, a mixture of two or more types of elements may be dissolved in the mixed solvent S at once. On the other hand, solutions prepared by separately dissolving Group III-B metals in the mixed solvent S may be mixed together.

Steps of applying and firing a raw-material solution are described below. First, a coating film is formed in such a way that a raw-material solution for a chalcopyrite compound containing the Group I-B element, the Group III-B element, and the Group VI-B element is applied to the substrate 1 having the first electrode layer 2 (an A1 step).

Next, a precursor layer is formed in such a way that the coating film is heated in an atmosphere containing moisture or oxygen (an A2 step). The temperature at which the precursor layer is formed in the A2 step is, for example, 250° C. to 350° C. In the A2 step, oxygen is likely to remain on particles of the chalcopyrite compound. In other words, the amount of oxygen bonded to the surface of each chalcopyrite compound particle is increased through the A2 step.

Next, a semiconductor layer is formed in such a way that the precursor layer is heated at 500° C. to 600° C. for 10 to 60 minutes in an atmosphere containing hydrogen and the Group VI-B element (an A3 step). In the A3 step, the concentration of the Group VI-B element may be, for example, 50 ppmv to 100 ppmv. When the precursor layer is heated in the atmosphere containing such a high concentration of the Group VI-B element, a compound which is contained in the precursor layer and which contains the Group VI-B element, for example, CuSe or In₂Se, is in a liquid state. On the other hand, a compound which is bonded to remaining oxygen in the A2 step and which is contained in the precursor layer has a relatively high melting point and therefore is likely to be in a solid state. In the precursor layer, liquid phases aggregate due to surface tension and solid phases are likely to be arranged around an aggregate of the liquid phases during heating in the A3 step. Therefore, in the semiconductor layer, which is obtained by heating in the A3 step, oxygen is segregated at grain boundaries. That is, in the semiconductor layer, the average concentration of oxygen at the grain boundaries is higher than the average concentration of oxygen in the grains.

Through the above steps, the light-absorbing layer 3 can be formed such that the average atomic concentration of oxygen at the grain boundaries is greater than that of oxygen in the grains. In the case of preparing the light-absorbing layer 3 by stacking a plurality of semiconductor layers, for example, the above A1 to A3 steps may be repeated. Another method for preparing the light-absorbing layer 3 by stacking a plurality of semiconductor layers may be as follows: after a plurality of precursor layers are formed by repeating the A1 and A2 steps, the precursor layers are heated in the A3 step.

The light-absorbing layer 3 may contain sodium. In this case, the average atomic concentration of sodium at the grain boundaries in the light-absorbing layer 3 may be greater than the average atomic concentration of sodium in the grains in the light-absorbing layer 3. This allows the recombination of electrons and holes at the grain boundaries to be efficiently reduced. When a large amount of sodium is present in the light-absorbing layer 3, the resistance of the light-absorbing layer 3 is excessively reduced. When the light-absorbing layer 3 has excessively low resistance, leakage is likely to occur therein. Therefore, in the light-absorbing layer 3, sodium is preferably segregated at the grain boundaries, at which recombination is more likely to occur than in the grains, such that the amount of sodium in the whole light-absorbing layer 3 is not increased. In this case, the average atomic concentration of sodium at the grain boundaries in the light-absorbing layer 3 is preferably 0.05 atomic percent to 20 atomic percent greater than the average atomic concentration of sodium in the grains in the light-absorbing layer 3. This allows the occurrence of recombination to be reduced and also allows the occurrence of leakage to be reduced. Incidentally, the average atomic concentration of sodium in the grains in the light-absorbing layer 3 may be 0 atomic percent to 0.05 atomic percent.

Five spots in each of the grains and grain boundaries in the light-absorbing layer 3 have been actually analyzed for composition by energy dispersive X-ray spectroscopy using a transmission electron microscope. The average atomic concentration of sodium was calculated from the average values. As a result, the average atomic concentration of sodium at the grain boundaries in the light-absorbing layer 3 was 5 atomic percent. Furthermore, the average atomic concentration of sodium in the grains in the light-absorbing layer 3 was 0.02 atomic percent. In the photoelectric converter 10, the occurrence of recombination can be reduced and the occurrence of leakage can be reduced. This leads to an increase in photoelectric conversion efficiency. In the method for preparing the light-absorbing layer 3, for example, a raw-material solution containing sodium perchlorate may be used in the A1 step. According to this method, sodium ionized in this raw-material solution is likely to remain on particles of the chalcopyrite compound semiconductor and therefore the atomic concentration of sodium at grain boundaries can be adjusted to be higher than the atomic concentration of sodium in grains. To this raw-material solution, about 500 ppm to 3,000 ppm of sodium perchlorate may be added.

When the light-absorbing layer 3 contains copper, the average atomic concentration of copper at the grain boundaries in the light-absorbing layer 3 may be less than the average atomic concentration of copper in the grains in the light-absorbing layer 3. In the photoelectric converter 10, the level of the valence band of the light-absorbing layer 3 is low and therefore the band gap at the grain boundaries is likely to be increased. As a result, the occurrence of recombination can be reduced and therefore the photoelectric conversion efficiency can be enhanced.

Five spots in each of the grains and grain boundaries in the light-absorbing layer 3 have been actually analyzed for composition by energy dispersive X-ray spectroscopy using a transmission electron microscope. The average atomic concentration of copper was calculated from the average values. As a result, the average atomic concentration of copper at the grain boundaries in the light-absorbing layer 3 was 17.5 atomic percent. Furthermore, the atomic concentration of copper in the grains in the light-absorbing layer 3 was 21.5 atomic percent.

An example of the method for preparing the light-absorbing layer 3 is as described below. In the A2 step, the coating film is heat-treated at 230° C. to 350° C. for 10 minutes in a nitrogen atmosphere containing 50 ppmv to 200 ppmv of water vapor, whereby the precursor layer is obtained. Next, in the A3 step, after being maintained at a temperature of 350° C. to 450° C. for 10 minutes to 30 minutes in a hydrogen atmosphere containing 2×10⁻² mg/L·minute to 5×10⁻² mg/L·minute of selenium vapor, the precursor layer is fired at a temperature of 500° C. to 600° C. for about 10 minutes to 60 minutes, whereby the light-absorbing layer 3 can be obtained. In an atmosphere, maintained at a low temperature of 350° C. to 450° C., containing selenium vapor, the Group III-B element is more likely to diffuse in selenium vapor than copper. Therefore, the Group III-B element is likely to be segregated on the surfaces of grains, that is, at grain boundaries. As a result, the atomic concentration of copper at the grain boundaries is relatively less than the atomic concentration of copper in the grains. In addition, when sodium is present at the grain boundaries in the light-absorbing layer 3, the resistance of the light-absorbing layer 3 can be increased by reducing the atomic concentration of copper at the grain boundaries; hence, the reduction in resistance of the light-absorbing layer 2 due to sodium can be reduced.

When the light-absorbing layer 3 contains copper, the elemental ratio of copper to the Group III-B element at the grain boundaries in the light-absorbing layer 3 may be greater than the elemental ratio of copper to the Group III-B element in the grains in the light-absorbing layer 3. This leads to the increase in carrier concentration of the light-absorbing layer 3. As a result, the resistance of the light-absorbing layer 3 can be reduced and therefore the photoelectric conversion efficiency is increased. In this case, the elemental ratio (copper/Group III-B element) of copper to the Group III-B element at the grain boundaries in the light-absorbing layer 3 may be 2 times to 3.5 times greater than the elemental ratio of copper to the Group III-B element in the grains in the light-absorbing layer 3. Incidentally, the elemental ratio of copper to the Group III-B element in the grains in the light-absorbing layer 3 may range from 0.7 to 1. According to such a range of the atomic concentration, the occurrence of leakage due to the excessive reduction in resistance of the light-absorbing layer 3 can be reduced.

Ten spots in each of the grains and grain boundaries in the light-absorbing layer 3 have been actually analyzed for composition by energy dispersive X-ray spectroscopy using a transmission electron microscope. The average atomic concentration of selenium was calculated from the average values. As a result, the elemental ratio of copper to the Group III-B element at the grain boundaries in the light-absorbing layer 3 was 2.47. Furthermore, the elemental ratio of copper to the Group III-B element in the grains in the light-absorbing layer 3 was 0.9. In the photoelectric converter 10, the recombination of electrons and holes is reduced, leading to an increase in photoelectric conversion efficiency.

An example of the method for preparing the light-absorbing layer 3 is as described below. In the A2 step, the coating film is heat-treated at 230° C. to 350° C. for 10 minutes in a nitrogen atmosphere containing 50 ppmv to 200 ppmv of water vapor, whereby the precursor layer is obtained. Next, in the A3 step, the precursor layer is fired at a temperature of 500° C. to 600° C. for about 10 minutes to 60 minutes in a hydrogen atmosphere containing 0.5×10⁻² mg/L·minute to 3×10⁻² mg/L·minute of the vapor of the Group VI-B element (for example, selenium vapor), whereby the light-absorbing layer 3 can be obtained. According to this method, the surroundings of a solid of a compound containing the Group III-B element are likely to be coated with liquid copper. This allows the elemental ratio of copper to the Group III-B element at grain boundaries to be relatively higher than the elemental ratio of copper to the Group III-B element in grains.

When the light-absorbing layer 3 contains selenium, the elemental ratio of selenium to the Group III-B element at the grain boundaries in the light-absorbing layer 3 may be greater than the elemental ratio of copper to the Group III-B element in the grains in the light-absorbing layer 3. This allows the energy gap between the conduction band of the grain boundaries and the valence band in the grains to be large; hence, the recombination of electrons and holes is reduced. This results in an increase in photoelectric conversion efficiency. Herein, the elemental ratio of selenium to the Group III-B element at the grain boundaries in the light-absorbing layer 3 may range from 2.25 to 3.25. This allows the occurrence of recombination to be reduced. Incidentally, the elemental ratio of selenium to the Group III-B element in the grains in the light-absorbing layer 3 may range from 1.80 to 2.10.

Five spots in each of the grains and grain boundaries in the light-absorbing layer 3 have been actually analyzed for composition by energy dispersive X-ray spectroscopy using a transmission electron microscope. The average atomic concentration of selenium was calculated from the average values. As a result, the elemental ratio of selenium to the Group III-B element at the grain boundaries in the light-absorbing layer 3 was 2.46. Furthermore, the atomic concentration of selenium in the grains in the light-absorbing layer 3 was 2.02. In the photoelectric converter 10, the recombination of electrons and holes is reduced, leading to an increase in photoelectric conversion efficiency.

An example of the method for preparing the light-absorbing layer 3 is as described below. In the A2 step, the coating film is heat-treated at 230° C. to 350° C. for 10 minutes in a nitrogen atmosphere containing 50 ppmv to 200 ppmv of water vapor, whereby the precursor layer is obtained. Next, in the A3 step, the precursor layer is fired at a temperature of 500° C. to 600° C. for about 40 minutes to 120 minutes in a hydrogen atmosphere containing 0.5×10⁻² mg/L·minute to 3×10⁻² mg/L·minute of selenium vapor, whereby the light-absorbing layer 3 can be obtained. According to this method, diffused selenium is likely to adhere to the surroundings of a solid of a compound containing the Group III-B element. This allows the elemental ratio of selenium to the Group III-B element at grain boundaries to be relatively higher than the elemental ratio of selenium to the Group III-B element in grains.

The buffer layers 4 are placed on the light-absorbing layers 3. Each of the buffer layers 4 is a semiconductor layer that forms a heterojunction (pn junction) with a corresponding one of the light-absorbing layer 3. Therefore, a pn junction is present at or near each of the interfaces between the light-absorbing layers 3 and the buffer layers 4. When the light-absorbing layers 3 are p-type semiconductors, the buffer layers 4 are n-type semiconductors. When the buffer layers have a resistivity of 1 Ω·cm or more, the leakage current can be reduced. Examples of the buffer layers 4 include CdS, ZnS, ZnO, In₂S₂, In(OH, S), (Zn, In)(Se, OH), and (Zn, Mg)O. The buffer layers 4 are formed by, for example, a chemical bath deposition (CBD) process or the like. Incidentally, In(OH, S) is a compound mainly containing In, OH, and S. In addition, (Zn, In)(Se, OH) is a compound mainly containing Zn, In, Se, and OH. Furthermore, (Zn, Mg)O is a compound mainly containing Zn, Mg, and O. When the buffer layers 4 have the ability to transmit light with wavelengths similar to those of light absorbed by the light-absorbing layers 3, the absorption efficiency of the light-absorbing layers 3 can be increased.

When the buffer layers 4 contain indium (In), the second electrode layers 5 preferably contain indium oxide. This allows the change in conductivity due to the interdiffusion of an element between the buffer layers 4 and the second electrode layers 5 to be reduced. Furthermore, the light-absorbing layers 3 are preferably made of a chalcopyrite material containing indium. In this configuration, since the light-absorbing layers 3, the buffer layers 4, and the second electrode layers 5 contain indium, the change in conductivity or carrier concentration due to the interdiffusion of an element between these layers can be reduced.

When the buffer layers 4 mainly contain a Group III-VI compound, the moisture resistance of the photoelectric converter 10 can be increased. Incidentally, the Group III-VI compound is a compound containing the Group III-B element and the Group VI-B element. In addition, the expression “the buffer layers 4 mainly contain a Group III-VI compound” means that the concentration of the Group III-VI compound in the buffer layers 4 is 50 mole percent or more. Furthermore, the concentration of the Group III-VI compound in the buffer layers 4 may be 80 mole percent or more. Furthermore, the concentration of Zn in the buffer layers 4 may be 50 atomic percent or less. This leads to the increase in moisture resistance of the photoelectric converter 10. The concentration of Zn in the buffer layers 4 may be 20 atomic percent or less.

The buffer layers 4 may have a thickness of, for example, 10 nm to 200 nm or 100 nm to 200 nm. This allows the reduction in photoelectric conversion efficiency to be reduced under high-temperature, high-humidity conditions.

The second electrode layers 5 are, for example, transparent conductive films, made of ITO (indium tin oxide), ZnO, or the like, having a thickness of 0.05 μm to 3 μm. The second electrode layers 5 are formed by a sputtering process, a vapor deposition process, a chemical vapor deposition (CVD) process, or the like. The second electrode layers 5 are lower in resistivity than the buffer layers 4 and are those for extracting charges generated in the light-absorbing layers 3. When the second electrode layers 5 have a resistivity of less than 1 Ω·cm and a sheet resistance of 50 Ω/square or less, charges can be extracted well.

In order to increase the absorption efficiency of the light-absorbing layers 3, the second electrode layers 5 may have the high ability to transmit light absorbed by the light-absorbing layers 3. The second electrode layers 5 may have a thickness of 0.05 μm to 0.5 μm. This allows the second electrode layers 5 to have increased light transmittance and also allows the reflection of light to be reduced. Furthermore, the second electrode layers 5 enhance a light-scattering effect and can transmit the current generated by photoelectric conversion well. In addition, when the second electrode layers 5 are substantially equal in refractive index to the buffer layers 4, the reflection of light at the interfaces between the second electrode layers 5 and the buffer layers 4 can be reduced.

The second electrode layers 5 preferably mainly contain the Group III-VI compound. This allows the photoelectric converter 10 to have increased moisture resistance. Incidentally, the expression “the second electrode layers 5 mainly contain the Group III-VI compound” means that the concentration of the Group III-VI compound in the second electrode layers 5 is 50 mole percent or more. Furthermore, the concentration of the Group III-VI compound in the second electrode layers 5 may be 80 mole percent or more. Furthermore, the concentration of Zn in the second electrode layers 5 may be 50 atomic percent or less. This leads to the increase in moisture resistance of the photoelectric converter 10. The concentration of Zn in the second electrode layers 5 may be 20 atomic percent or less.

In the photoelectric converter 10, combinations of the buffer layers 4 and the second electrode layers 5, that is, regions interposed between the light-absorbing layers 3 and the current-collecting electrodes 8, may mainly contain the Group III-VI compound. Incidentally, the expression “combinations of the buffer layers 4 and the second electrode layers 5 mainly contain the Group III-VI compound” means that the Group III-VI compound (when several types of Group III-VI compounds, the sum thereof) accounts for 50 mole percent or more of compounds making up the combinations of the buffer layers 4 and the second electrode layers 5. The Group III-VI compound may account for 80 mole percent or more. The concentration of Zn in the combinations of the buffer layers 4 and the second electrode layers 5 may be 50 atomic percent or less. This leads to the increase in moisture resistance of the photoelectric converter 10. The concentration of Zn in the combinations of the buffer layers 4 and the second electrode layers 5 may be 20 atomic percent or less.

The photoelectric converter 10 is electrically connected to the adjacent photoelectric converter 10 through the connection conductor 7. This allows the photoelectric converters 10 to be connected in series into a photoelectric conversion module 20 as shown in FIG. 1.

The connection conductor 7 connects the second electrode layers 5 and the third electrode layer 6. In other words, the connection conductor 7 connects the second electrode layers 5 of one of the neighboring photoelectric converters 10 to the third electrode layer 6 of the other photoelectric converter 10. The connection conductor 7 is placed so as to separate the light-absorbing layers 3 of the neighboring photoelectric converters 10. This allows the electricity converted from light in the light-absorbing layers 3 to be extracted by series connection in the form of a current. The connection conductor 7 may be formed together with the second electrode layers 5 in the same step so as to be combined with the second electrode layers 5. This allows a step of forming the connection conductor 7 to be simplified. Furthermore, according to this way, the connection conductor 7 and the second electrode layers 5 can be electrically connected to each other well and therefore the reliably can be enhanced.

The current-collecting electrodes 8 have a function of reducing the electrical resistance of the second electrode layers 5. This allows the current generated in the light-absorbing layers 3 to be efficiently extracted. This results in the increase in photoelectric conversion efficiency of each photoelectric converter 10.

As shown in, for example, FIG. 1, each current-collecting electrode 8 linearly extends from an end of the photoelectric converter 10 to the connection conductor 7. Therefore, charges generated by the photoelectric conversion of the light-absorbing layers 3 are collected by the current-collecting electrodes 8 through the second electrode layers 5. The collected charges are transmitted to the adjacent photoelectric converter 10. Thus, the presence of the current-collecting electrodes 8 allows the current generated in the light-absorbing layers 3 to be efficiently extracted even if the second electrode layers 5 are thin. This results in an increase in power generation efficiency.

The current-collecting electrodes 8, which are linear, may have a width of, for example, 50 μm to 400 μm. This allows the conductivity to be ensured without excessively reducing the light-receiving area of each light-absorbing layer 3. In addition, the current-collecting electrodes 8 may each include a plurality of separate branched portions.

The current-collecting electrodes 8 are formed using, for example, a metal paste prepared by dispersing a metal powder such as an Ag powder in a resin binder or the like. The current-collecting electrodes 8 are formed in such a way that desired patterns are printed with the metal paste by, for example, screen printing or the like and are then cured.

The current-collecting electrodes 8 may contain solder. This allows the resistance to bending stress to be enhanced and also allows the resistance to be reduced. The current-collecting electrodes 8 may contain two or more types of metals having different melting points. In this case, the current-collecting electrodes 8 are preferably those formed in such a way that at least one type of metal is melted, is heated at a temperature at which another one type of metal is not melted, and is then hardened. This allows a low-melting point metal to be preferentially melted; hence, the current-collecting electrodes 8 are dense. Therefore, the current-collecting electrodes 8 have reduced resistance. On the other hand, a high-melting point metal acts to maintain the shape of the current-collecting electrodes 8.

Each of the current-collecting electrodes 8 is placed so as to reach an outer end portion of a corresponding one of the light-absorbing layers 3 in plan view. In this configuration, the current-collecting electrodes 8 can protect the peripheries of the light-absorbing layers 3 and can reduce the occurrence of defects in the peripheries of the light-absorbing layers 3. According to the current-collecting electrodes 8, the currents generated in the peripheries of the light-absorbing layers 3 can be efficiently extracted. This leads to an increase in power generation efficiency.

In this configuration, since the current-collecting electrodes 8 can protect the peripheries of the light-absorbing layers 3, the sum of the thicknesses of members arranged between the first electrode layer 2 and the current-collecting electrodes 8 may be small. Thus, the members can be downsized. Furthermore, steps of forming the light-absorbing layers 3, the buffer layers 4, and the second electrode layers 5, which corresponding to the members, can be shortened. The sum of the thickness of each of the light-absorbing layers 3, that of a corresponding one of the buffer layers 4, and that of a corresponding one of the second electrode layers 5 may be, for example, 1.56 μm to 2.7 μm. In particular, the thickness of each light-absorbing layer 3 is 1 μm to 2.5 μm. The thickness of each buffer layer 4 is 0.01 μm to 0.2 μm. The thickness of each second electrode layer 5 is 0.05 μm to 0.5 μm.

In an outer end portion of each light-absorbing layer 3, an end surface of a corresponding one of the current-collecting electrodes 8, an end surface of a corresponding one of the second electrode layers 5, and an end surface of the light-absorbing layer 3 may be in the same plane. This allows the current converted from light in the periphery of the light-absorbing layer 3 to be extracted well. When each current-collecting electrode 8 is viewed from above, the current-collecting electrode 8 need not reach the outer end portion of the light-absorbing layer 3. When the distance between the outer end portion of the light-absorbing layer 3 and an and portion of the current-collecting electrode 8 is, for example, 1,000 μm or less, the occurrence and progress of defects originating from the outer end portion of the light-absorbing layer 3 can be reduced.

The present invention is not limited to the above embodiments. Various modifications may be made without departing from the scope of the present invention.

### REFERENCE SIGNS LIST

1 Substrate

2 First electrode layer (electrode layer)

3 Light-absorbing layers

3a Pores

4 Buffer layers

5 Second electrode layers

6 Third electrode layer

7 Connection conductor

8 Current-collecting electrodes

10 Photoelectric converters

20 Photoelectric conversion module

1. A photoelectric converter comprising a light-absorbing layer, the light-absorbing layer comprising a plurality of crystalline grains which contain a Group I-III-VI chalcopyrite compound semiconductor,
wherein the light-absorbing layer contains oxygen and
wherein an average atomic concentration of oxygen at grain boundaries of the light-absorbing layer is larger than the average atomic concentration of oxygen in the grains of the light-absorbing layer.

2. The photoelectric converter according to claim 1, wherein
the light-absorbing layer further contains sodium, and
an average atomic concentration of sodium at the grain boundaries of the light-absorbing layer is larger than the average atomic concentration of sodium in the grains of the light-absorbing layer.

3. The photoelectric converter according to claim 1, wherein
the chalcopyrite compound semiconductor contains copper, and
an average atomic concentration of copper at the grain boundaries of the light-absorbing layer is less than the average atomic concentration of copper in the grains of the light-absorbing layer.

4. The photoelectric converter according to claim 1, wherein
the chalcopyrite compound semiconductor contains copper, and
a elemental ratio of copper to a Group III-B element at the grain boundaries of the light-absorbing layer is larger than the elemental ratio of copper to the Group III-B element of the grains in the light-absorbing layer.

5. The photoelectric converter according to claim 1, wherein
the chalcopyrite compound semiconductor contains selenium, and
a elemental ratio of selenium to a Group III-B element at the grain boundaries of the light-absorbing layer is larger than the elemental ratio of selenium to the Group III-B element in the grains of the light-absorbing layer.
